(19) United States
(12) Patent Application Publication
(10) Pub. No.: US 2002/0110983 A1
(43) Pub. Date: Aug. 15, 2002

(54) Method of fabricating a split-gate flash memory cell

(76) Inventors: Chih-Cheng Liu, Pan-Chiao City (TW); De-Yuan Wu, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/779,487

(22) Filed: Feb. 9, 2001

(51) Int. Cl. H01L 21/336

(52) U.S. Cl. 438/257

(57) ABSTRACT

A method of fabricating a split gate flash memory cell is provided in the present invention. Firstly, a cap layer is formed on the surface of a silicon base of the semiconductor wafer. The surface of the silicon base is then etched to form at least one shallow trench. The shallow trench comprises a vertical sidewall composed of a protion of the silicon base. Next, an ion implantation process is performed using the cap layer to as a mask in order to form a doped area in both the bottom surface of the shallow trench and the silicon base beneath the cap layer. The doped area functions as a source. A first dielectric layer, floating gate, second dielectric layer, and a control gate are formed, respectively, the width of the floating gate being shorter than the width of the first dielectric layer. Then, a third dielectric layer is formed on the control gate and the cap layer is removed. Finally, an electrical conduction layer is formed on the surface of the silicon base to function as a drain to complete the split gate flash memory cell of the present invention.

### BACKGROUND OF THE INVENTION

1. Field of the Invention

The present invention provides a method of fabricating a split-gate flash memory cell, more particularly, a method of decreasing the operational voltage of a split-gate flash memory cell.

2. Description of the Prior Art

Flash memory can be divided into a stacked-gate flash memory or a split-gate flash memory depending on its structure. The stacked gate flash memory cell comprises a floating gate for storage charge, a dielectric layer of oxide-nitride-oxide (ONO) structure, and a control gate for data access. The induced charge is stored in the stacked-gate according to the principle similar to that of the capacitor, whereby a signal of “1” is inputted into the memory. Additional energy is supplied to replace the data with new data.

Please refer to FIG. 1 of the schematic diagram of the cross-sectional structure of the stacked-gate flash memory cell 10 in the prior art. As shown in FIG. 1, a stacked gate 11 and a drain 22 and a source 24 comprises the stacked-gate flash memory cell 10. A gate oxide layer 12, a floating gate 14, a dielectric layer 16, and a control gate 18 are stacked, respectively, on the surface region of the silicon base 20 between the drain 22 and the source 24 to form the stacked gate 11. Data storage is achieved when thermal electrons produced around the drain 22 is ejected into the floating gate 14 across the gate oxide layer 12 via the channel hot electrons (CHE) effect. The small surface area of the stacked-gate flash memory cell 10 leads to the defect of overerase. However, the split-gate flash memory prevents overerase to avoid data-input error or to avoid inability to input data.

Please refer to FIG. 2 of the schematic diagram of the cross-sectional structure of the split-gate flash memory cell 30 in the prior art. As shown in FIG. 2, a gate oxide layer 32, a floating gate 34, a control gate 38, a drain 42, and a source 44 form the split-gate flash memory cell 30. The selective channel 31 is formed on the silicon base between the floating gate 34 and the source 44 and extended in the direction of the source 44 by the control gate 38. A dielectric layer 36 is formed between the control gate 38 and the floating gate 34. Although the split-gate flash memory solves the problem of overerase occurring in the stacked-gate flash memory, the value of the coupling ratio (CR) of the split-gate flash memory cell is low so as to be unable to increase the erasing speed. As well, are both the disadvantages of incomplete erasure and unstable functioning. Inaccuracy in the aim of the exposure alignment machine affects the overlapping area between the control gate 38 and the floating gate 34 to produce an unstable channel current during data input.

Please refer to FIG. 3. FIG. 3 is the schematic diagram of an equivalent circuit 46 of the split gate flash memory cell 30 shown in FIG. 2. As shown in FIG. 3, C₁ is the electrical capacitor between the floating gate 34 and the control gate 38. C₂ is the electrical capacitor between the floating gate 34 and the source 44. C₃ is the capacitor between the floating gate 34 and the channel on the surface of the silicon base 40. C₄ is the capacitor between the floating gate 34 and the drain 42. Thus, the value of the CR of the split gate flash memory cell 30 can be defined as following:

CR=C₁/(C₁+C₂+C₃+C₄)

The value of CR is the performance target of the split gate flash memory cell 30. When the operational voltage needed during the data-input or erase operation of the flash memory is low, the value of the CR is high resulting in improved the performance. Increase in the value of C₁ or decrease in the value of C₂, C₃, or C₄ results in an increase in the value of CR increase. Since the value of the capacitor is proportional to the the area of the capacitor, increasing the area of the capacitor between the floating gate 34 and the control gate 38 also increases the value of C₁. In addition, decreasing the area of the capacitor of the channel between the surface of the silicon base 40 and the floating gate 34 effectively decreases the value of C₃.

Please refer to FIG. 4 to FIG. 8 of the schematic diagrams of the method of making a split-gate flash memory cell on a semiconductor wafer 50 according to the prior art. As shown in FIG. 4, the semiconductor wafer 50 comprises a silicon base 52, a silicon oxide layer functioning as a gate oxide layer 54, a polysilicon layer 56, and a dielectric layer 58 composed of silicon formed, respectively, on the semiconductor wafer 50. As shown in FIG. 5, aphotoresist layer (not shown) is formed atop the dielectric layer 58, and defined using a lithographic process. Then, the portions of the polysilicon layer 56 and the dielectric layer 58 not covered by the photoresist layer are removed down to the surface of the gate oxide layer 54 to form a control gate 60. A thermal oxidation process is then performed to remove the photoresist layer and to form the dielectric layer 62 adjacent to the control gate 60.

And then as shown in FIG. 6, a polysilicon layer (not shown) is again deposited on the surface of the semiconductor wafer 50 to completely cover the dielectric layer 58. Next, an etching back process is performed to remove portions of the polysilicon layer and the gate oxide layer 54 down to the surface of the silicon base 52 to form a spacer 63 on either side of both the dielectric layer 62 and the dielectric layer 58. And then as shown in FIG. 7, a photoresist layer 66 is formed on the surface of the semiconductor wafer 50 and covering one of the two spacers 63. The other spacer 63 and the gate oxide layer 54 not covered by the photoresist layer 66 are removed in an etching process down to the surface of the silicon base 52. The surface of the remaining gate oxide layer 54 aligns with that of both the dielectric layers 58, 62. The remaining spacer 63 functions as a floating gate 64 of the gate flash memory cell 80.

Following the removal of the photoresist layer 66, as shown in FIG. 8, an ion implantation process is used to form two doped areas (not shown) on the surface of the silicon base 52 not covered by the gate oxide layer 54. Then, a rapid thermal process (RTP) is used to allow the dopants to diffuse into the silicon base 52 to form a drain 68 and source 70 adjacent to the gate oxide layer 54 to complete the fabrication of the split flash memory cell 80.

Since the spacer 63 is used to fabricate the floating gate 64 of the split flash memory cell 80, misalignment of the exposure machine is avoided and self-aligned contact (SAC) is achieved. However, the etching process used to form the spacer 63 is unable to efficiently control the thickness of the floating gate 64. The inability to effectively maintain a constant or decreased thickness of the floating gate influences the quality of the memory cell.

### SUMMARY OF THE INVENTION

The object of the present invention provides a method of fabricating the split flash memory cell in order to decrease both the thickness of the floating gate and the operational voltage of the memory to improve product quality.

Another object of the present invention provides a method of fabricating the split-gate flash memory cell in order to increase the CR of the split-gate flash memory cell and improve erasure speed.

In the present invention, a cap layer is fist formed on the surface of the silicon base of the semiconductor wafer. Then, an etching process is performed on the surface of the silicon base to form at least one shallow trench. The shallow trench comprises of vertical sidewalls formed by the silicon base. Next, an ion implantation process is performed using the cap layer as a mask to form a doped area in the silicon base beneath the cap layer and on the bottom surface of the trench. The doped area functions as a source. Then, a first dielectric layer, a floating gate layer, a second dielectric layer, and a control gate layer are formed, respectively, on the bottom surface of the shallow trench. The width of the floating gate layer is shorter than that of the first dielectric layer. Next, a third dielectric layer is formed on the control gate layer followed by the removal of the cap layer. Finally, an electrical conducting layer is formed on the surface of the silicon base and functions as a drain to complete the fabrication of the split flash memory cell of the present invention.

Since both the control gate and floating gate of the split gate flash memory cell are formed during the CVD process, the thickness of the floating gate channel is effectively decreased to approximately three to four times the length of the electron mean free path. As well,the operational voltage of the flash memory cell is decreased so that the thermal electrons easily enter the floating gate.

As well, the floating gate and subsequent components are formed on a large contact area in a shallow trench adjacent to a gate oxide layer to increase the value of the CR and thereby increase the access speed of the split gate flash memory cell.

### BRIEF DESCRIPTION OF THE DRAWINGS

FIG. 1 is a schematic diagram of the cross-sectional structure of the stacked gate flash memory cell in the prior art.

FIG. 2 is the schematic diagram of the cross-sectional structure of the split gate flash memory cell in the prior art.

FIG. 3 is the schematic diagram of the effective circuit in the split gate flash memory in FIG. 2.

FIG. 4 to FIG. 8 are the schematic diagrams of the method of fabricating the split gate flash memory cell in the prior art.

FIG. 9 to FIG. 15 are the schematic diagrams of the method of fabricating the split gate flash memory cell in the present invention.

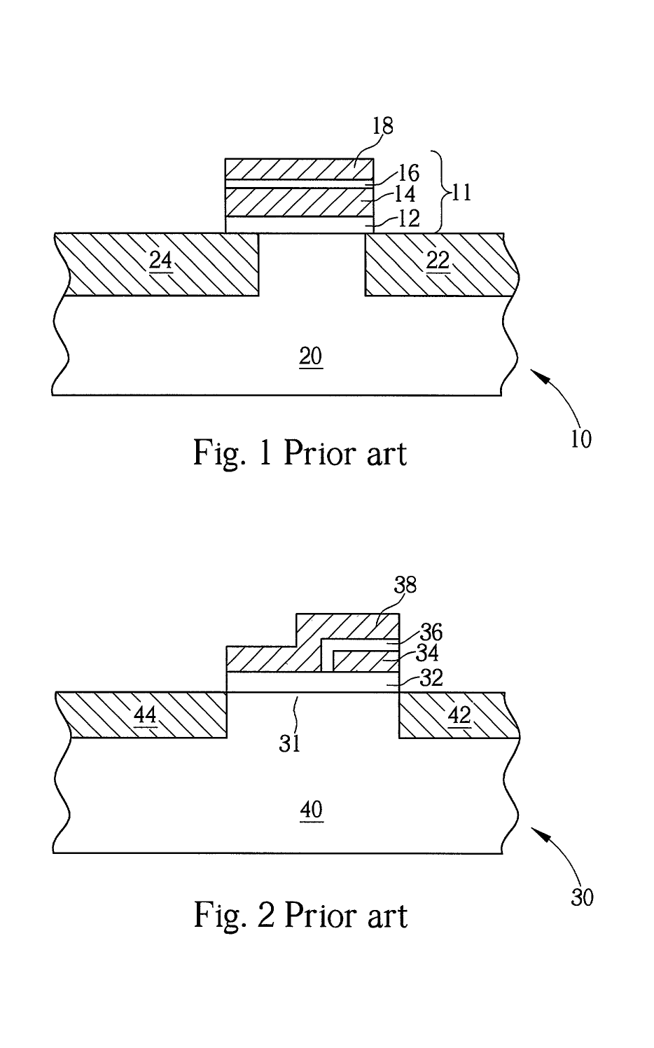

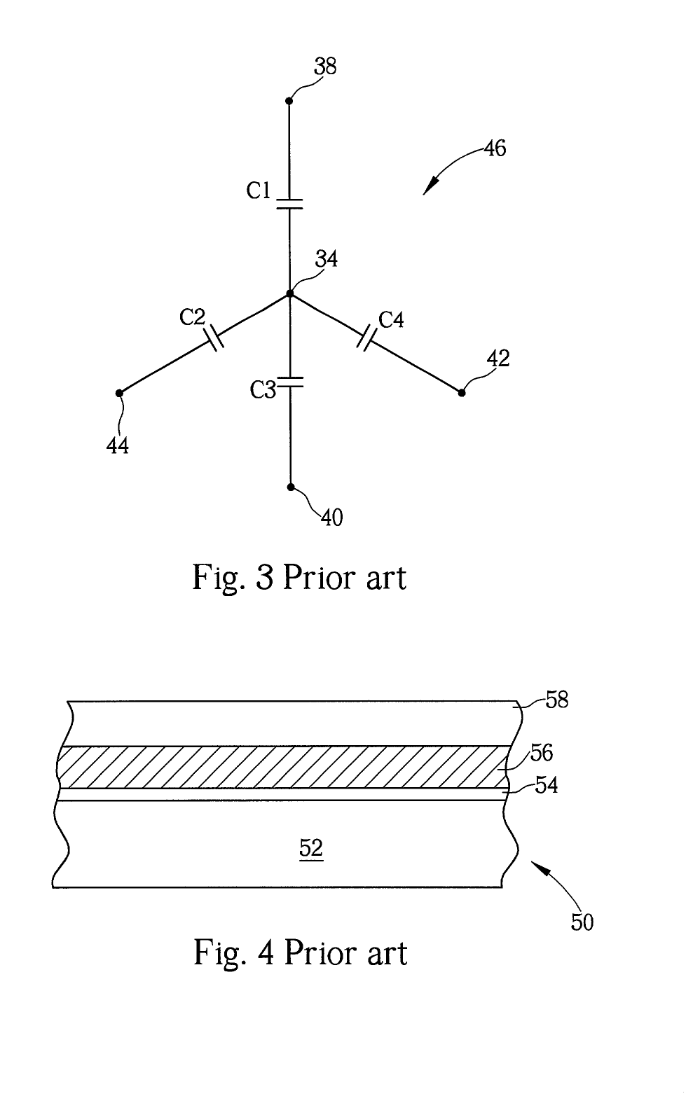

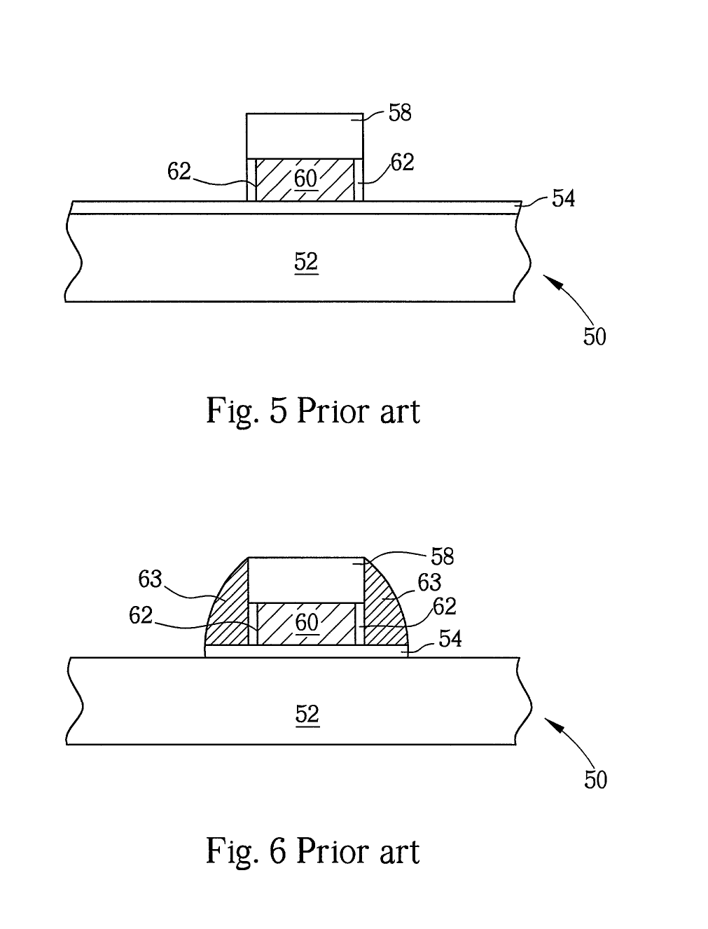

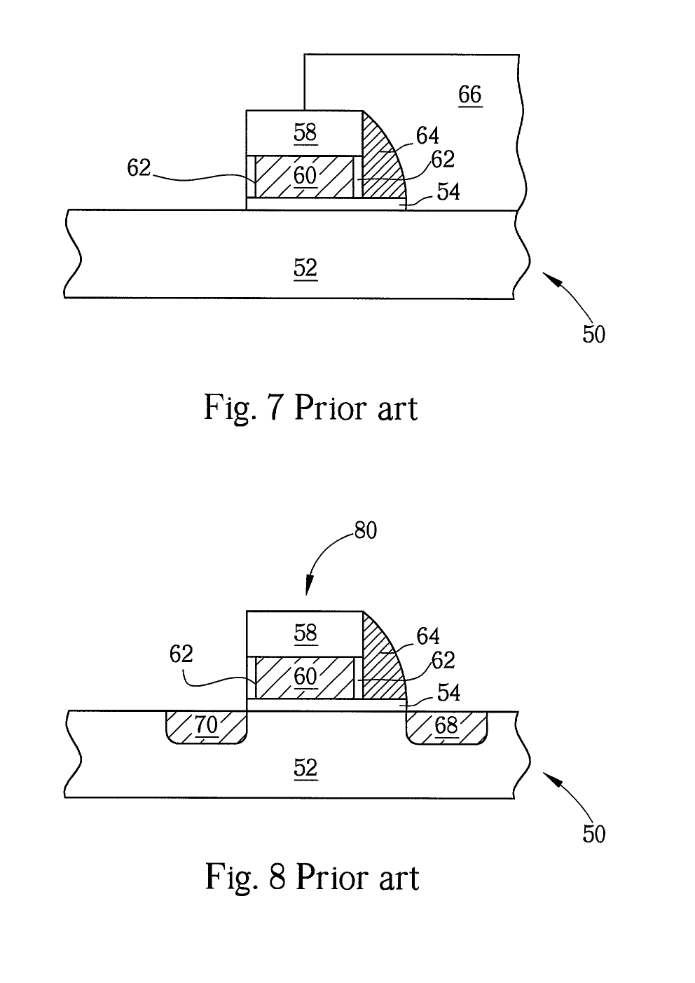

### DETAILED DESCRIPTION OF THE PREFERRED EMBODIMENT

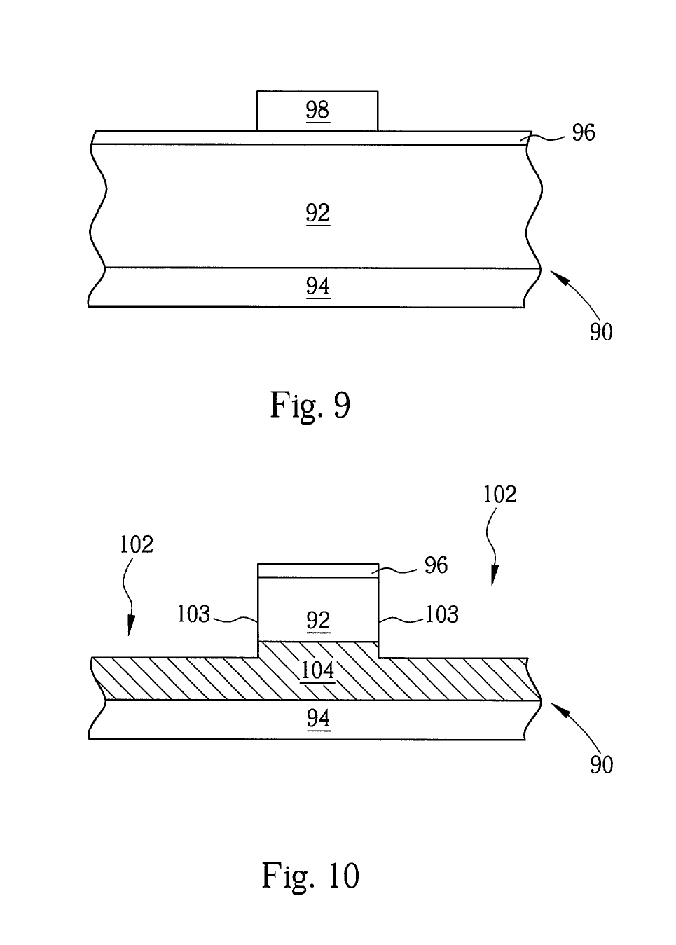

Please refer to FIG. 9 to FIG. 15 of the schematic diagrams of the method of fabricating the split gate flash memory cell 126 on the semiconductor wafer 90 in the present invention. In the preferred embodiments, a silicon-on-insulator(SOI) base is formed on the semiconductor wafer 90 by performing a general SIMOX process. The SOI comprises a glass base or a single crystal silicon base(not shown). A silicon dioxide dielectric layer 94 is deposited on the glass base or the single crystal silicon base. A single crystal P-type silicon substrate 92 with a thickness ranging from 0.5 micrometer to 1 micrometer is formed on the silicon dioxide dielectric layer 94.

As shown in FIG. 9, a silicon nitride layer of a thickness of about 2000 angstroms(Å) is formed on the surface of the silicon base 92 as a cap layer 96 to function as an etching mask in the following etching process. Next, a patterned photoresist layer 98 is formed on the surface of the cap layer 96 using a lithographic process. As shown in FIG. 10, the silicon base 92 not covered by the photoresist layer 98 is etched by a reactive ion etching(RIE) process to form a shallow trench 102 with a thickness of 0.5 micrometer (μm). The shallow trench 102 comprises vertical sidewalls 103 composed of a portion of the silicon base 92. A polysilicon floating gate is placed in the shallow trench 102 in a subsequent process and thus, the depth of the shallow trench 102 is the length of the channel of the floating gate. Next, the photoresist layer 98 is completely removed in the surroundings of the dry oxygen plasma.

Two ion implantation processes are then performed on the silicon base 92 using the cap layer 96 as a mask. First, high dosage arsenic is used as the primary dopant to dope the silicon base 92 at the bottom surface of the shallow trench 102. The implantation energy is about 30 KeV and the implantation dosage is between the range of 10¹⁴ ions/cm² to 10¹⁵ ions/cm². Then, a second ion implantation process at an angle of inclination is used to continuously implant the portion of the silicon base 92 beneath the cap layer 96. The implantation energy is between the range of 200 KeV to 300 KeV and the implantation dosage is between the range of 10¹⁴ ions/cm² to 10¹⁵ ions/cm² with an angle of inclination formed between the bottom surface of the shallow trench 102 and the emitting angle of the ions. The N-type doped area on the dielectric layer 94 and beneath the stacked structure of the P-type silicon base 92 functions as a source 104 of the memory cell 126. A thermal process or a rapid thermal annealing (RTA) process is used to activate the dopant in the N-type doped area 104 following the ion implantation process.

In another embodiment of the present invention, a third ion implantation process is performed following the second ion implantation. The ions are emitted at a different angle in order to form a required concentration distribution in the silicon base 92. As well, different potentials and dosages are used in the ion implantation processes according to both the impurity profile and potential contour in the P-type silicon base 92.

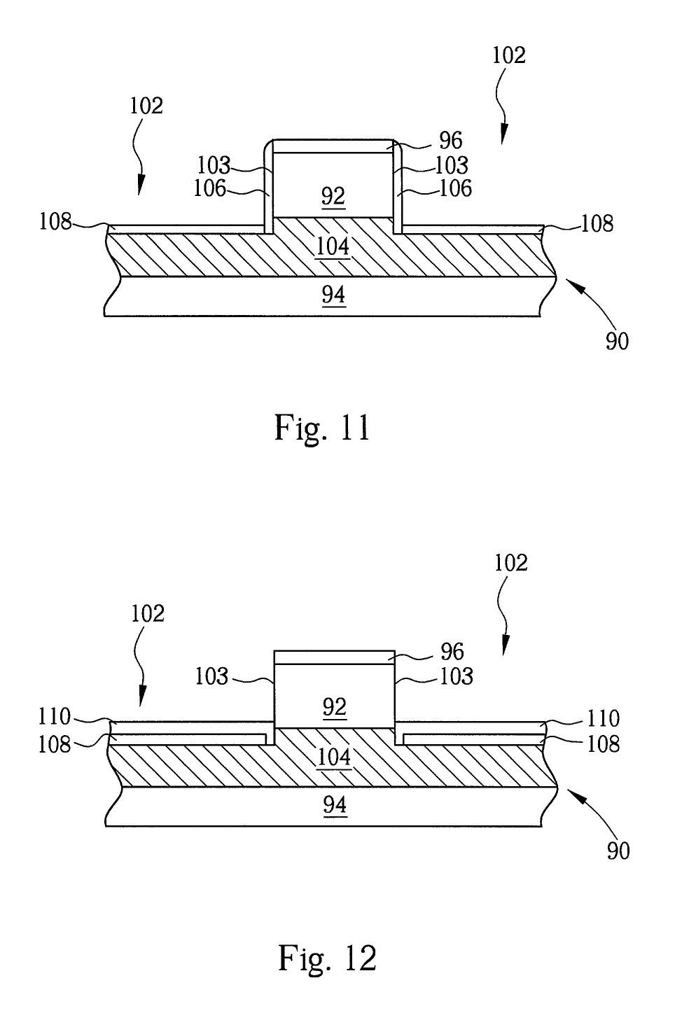

As shown in FIG. 11, a uniform silicon dioxide layer(not shown) or a silicon nitride layer are formed on the surface of the semiconductor wafer 90 by performing a CVD process. An anisotropic etching process is then performed to remove the silicon dioxide layer or the silicon nitride layer covering the surface of the source 104 and the cap layer 96 in order to form a spacer 106 on the vertical sidewall 103. Next, a self-aligned silicide(salicide) process is performed on the surface of the source 104 using the spacer 106 as a salicide block(SAB) in order to form a salicide layer 108 on the surface of the silicon base 92 on the bottom surface of the shallow trench 102. The salicide layer 108 functions as a source line.

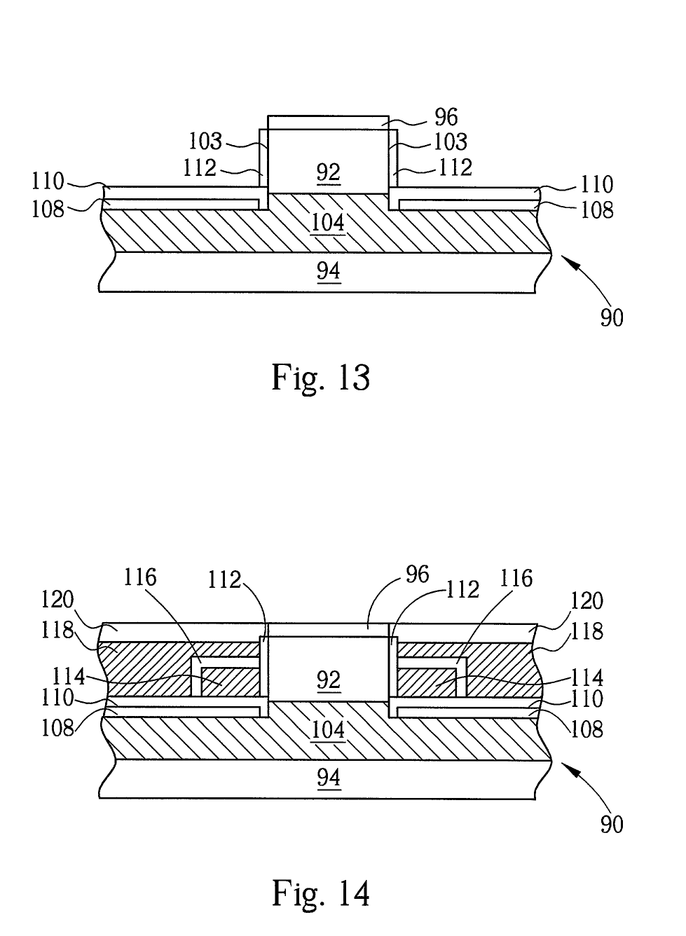

As shown in FIG. 12, a wet etching process is then performed. For example, the silicon dioxide spacer 106 is selectively removed using hydrofluoric acid(HF) in order to expose the vertical sidewall 103. Next, a CVD process and an etching process are performed to form a dielectric layer 110 on the surface of the semiconductor wafer 90. The dielectric layer 110 covers the surface of the silicide 108 and a portion of the vertical sidewall 103. And then as shown in FIG. 13, a thermal oxidation process is used to form a silicon dioxide layer with a thickness ranging from 1 nanometer to 10 nanometers on the surface of the exposed vertical sidewall 103. The silicon dioxide layer functions as a gate oxide layer 112.

As shown in FIG. 14, a doped polysilicon layer (not shown) is formed on the surface of the dielectric layer 110 adjacent to the gate oxide layer 112 using a CVD process on the surface of the semiconductor wafer 90. The polysilicon layer functions as an electrical conduction layer. Then, an etching process is performed to remove a portion of the electrical conduction layer and form a floating gate 114 of a thickness between 15 nanometers(nm) to 50 nanometers(nm) on the surface of the dielectric layer 110. The thickness of the deposition of the electrical conduction layer is the same as the floating gate channel length (L_{FG}). The signal access unit is divided into its components using a lithographic and etching process. The thickness of the deposition of the floating gate 114 can be controlled to be about 3 or 4 times the length of the electron mean free path. The width of the floating gate 114 after the etching process must be less than the width of the dielectric layer 110. For example, the width of the floating gate 114 is about a half to three-quarters the width of the dielectric layer 110. Also, the floating gate 114 and subsequent components are formed on a large contact area in the shallow trench 102 adjacent to the gate oxide layer 112 to increase the CR of the split gate flash memory cell 126.

A dielectric layer 116 composed of silicon dioxide is formed on the top and side surface of the floating gate 114 by the use of a thermal oxidation process. A control gate 118 composed of doped polysilicon is formed in the shallow trench 102 and covering the dielectric layer 116 using a CVD and etching process. The surface of the control gate 118 is thereby lower than that of the silicon base 92. Next, a dielectric layer 120 composed of silicon dioxide is formed on the surface of the control gate 118, and is aligned with the surface of the cap layer 96.

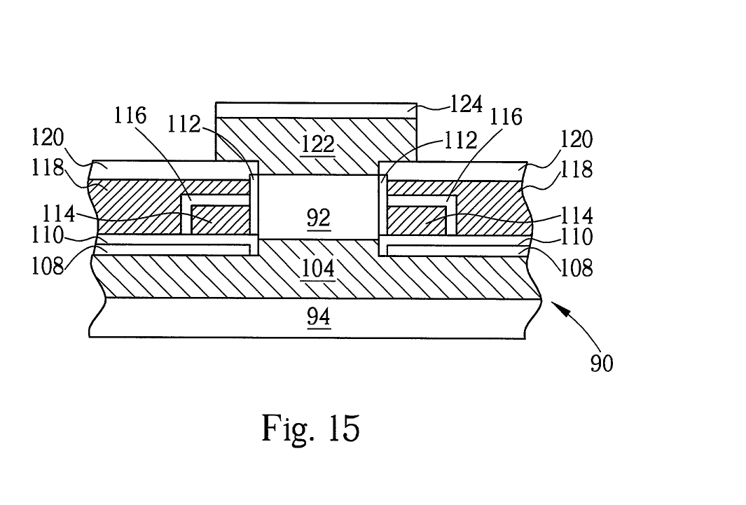

As shown in FIG. 15, for example, the cap layer 96 is selectively removed by performing a wet etching process using a phosphoric acid(H₃PO₄) solution. The width of the doped polysilicon layer is longer than the width of the cap layer 96 in FIG. 14. A doped polysilicon layer (not shown) is formed on the surface of the silicon base 92 and covering a portion of the dielectric layer 120 by CVD, lithographic and etching processes. The doped polysilicon layer functions as a bit line. A drain 122 of the memory cell 126 is thus formed and is composed of the overlap area of the bit line with the floating gate 114. Finally, a silicide layer 124 is formed by performing a salicide process on the surface of the bit line to complete the fabrication of the vertical burried split gate flash memory cell 126.

When the control gate 118 is subjected to a voltage greater than the threshold voltage of the memory cell 126, channel hot electrons (CHE) are emitted from the source 104 and travel along the vertical channel formed in the silicon base 92 to the drain 122. A portion of the CHE passes a very short distance to directly and rapidly enter the floating gate 114 via the gate oxide layer 112, also known as a tunnel oxide layer, in order to access data. The characteristics of the vertical type split gate flash memory cell 126 in the present invention included the following:

(1) The vertical type split gate memory device is buried beneath the surface of the SOI base.

(2) The thickness of the floating gate 114 can be effectively controlled in order to achieve the ballistic CHE performance.

(3)The area of the memory device is decreased to 4F2.

(4)The flash memory device has a low gate voltage.

(5)The vertical stacked structure allows the thermal electrons to be injected into the floating gate 118 across a very short distance via the gate oxide layer 112 to access data. As a result, phonon scattering is prevented.

(6) The larger contact area between the control gate 118 and the floating gate 114 increases the CR of the split gate flash memory cell to improve the speed of access.

In comparison to the prior art, both the control gate and the floating gate of the vertically split gate flash memory cell in the present invention is formed using a CVD process. The control of the thickness in deposition process also effectively decreases the length of the floating gate channel to approximately three to four times the length of the electron mean free path. Thus, the thickness of the floating gate is decreased from the degree of μm in the prior art to the degree of nm in the present invention. Also, the thickness of the tunneling oxide layer is decreased and the operational voltage of the memory cell is also decreased from 10 volts to 5 volts, to prevent both damage due to high pressure as well electrical energy waste. Lastly, the step structure formed by the floating gate and the control gate allows for a greater contact area between the floating gate and the control gate to increase the CR of the split gate flash memory cell and improve accessing.

Those skilled in the art will readily observe that numerous modifications and alterations of the device may be made while retaining the teachings of the invention. Accordingly,the above disclosure should be construed as limited only by the metes and bounds of the appended claims.

What is claimed is:

1. A method of fabricating a split gate flash memory cell comprising:
providing a silicon base;
forming a cap layer on the surface of the silicon base;
performing a lithographic process and an etching process in order to form at least a shallow trench on the surface of the silicon base, the shallow trench comprising a vertical sidewall composed of a portion of the silicon base;
performing an ion implantation process to form a doped area in the silicon base beneath both the cap layer and on the bottom surface of the shallow trench using the cap layer as a mask, the doped area functioning as a source of the vertical type split gate flash memory cell;
forming a spacer on the vertical sidewall;
forming a silicide on the surface of the silicon base outside the spacer;
removing the spacer to expose the vertical sidewall;
forming a first dielectric layer adjacent to the vertical sidewall on the bottom surface of the shallow trench;
forming a floating gate adjacent to the vertical sidewall on a first dielectric layer, the width of the floating gate being shorter than the width of the first dielectric layer;
forming a second dielectric layer on the surface of the floating gate;
forming a control gate on a second dielectric layer, the surface of the control gate being lower than that of the surface of the silicon base;
forming a third dielectric layer on the control gate;
removing the cap layer;and
forming a electrical conduction layer on the surface of the silicon base to function as a drain of the vertical type split gate flash memory cell.

2. The method of claim 1 wherein the silicon base is a SOI base and the doped area adjacent to an isolation layer of the SOI base is formed by using two ion implantation processes of different potential energies.

3. The method of claim 1 wherein the thickness of the floating gate is about three times or four times of the length of the electron mean free path.

4. The method of claim 1 wherein the thickness of the floating gate is about 35 nanometers(nm).

5. The method of claim 1 wherein the process of fabricating both the floating gate and the control gate is a deposition process.

6. The method of claim 5 wherein the deposition process is a chemical vapor deposition(CVD) process.

7. The method of claim 1 wherein the vertical sidewall comprises both the tunnel oxide layer on the silicon base and the isolation layer between the floating gate and the control gate.

8. The method of claim 1 wherein a silicide is on the surface of the electrical conduction layer.

9. A method of fabricating a vertical flash memory cell on a semiconductor wafer comprising:
providing a silicon base;
performing a photolithographic process to form a cap layer on the surface of the silicon base and to define a vertical channel on the surface of the cap layer, the cap layer, except for the vertical channel, is removed down to a predetermined depth in the silicon base;
performing an ion implantation process on the surface of the silicon base using the cap layer as a mask in order to form a doped area in the silicon base;
forming a spacer adjacent to the both sides of a vertical channel, the spacer functioning as a salicide block(SAB) and the salicide being formed on the surface of the doped area outside the spacer;
forming a first dielectric layer on the surface of the salicide adjacent to the vertical channel after the spacer is removed;
forming a floating gate on the surface of the first dielectric layer and a control gate formed on the surface of the floating gate using a chemical vapor deposition process;
forming a second dielectric layer on the surface of the control gate;and
forming a doped polysilicon layer on the surface of the silicon base of the vertical channel to remove the cap layer;
controlling the thickness of both the floating gate and the control gate by the chemical vapor deposition process in order to decrease the operational voltage of the vertical flash memory cell.

10. The method of claim 9 wherein the vertical flash memory cell is the split gate flash memory cell and the width of the floating gate is about a half to three quarters of the width of the first dielectric layer in order to increase the CR of the split gate flash memory cell.

11. The method of claim 9 wherein the dielectric layer is positioned between the floating gate and the control gate and another dielectric layer is positioned over the control gate, the gate oxide layer, and the silicon base.

12. The method of claim 9 wherein the thickness of the floating gate is between 20 nanometers to 50 nanometers.

13. The method of claim 9 wherein the the operational voltage of the vertical flash memory cell is lower than 5 volts.

14. The method of claim 9 wherein the base is a SOI base and the doped area is formed adjacent to the isolation layer in the SOI base.

15. The method of claim 9 wherein the cap layer is composed of silicon nitride(SiNₓ).

16. The method of claim 9 wherein the doped area and the doped polysilicon layer are the source and drain, respectively, of the vertical flash memory cell.
